(19) United States
(12) Patent Application Publication
(10) Pub. No.: US 2012/0181576 A1
(43) Pub. Date: Jul. 19, 2012

(54) INSULATED GATE BIPOLAR TRANSISTOR

(75) Inventors: Yung-Fa LIN, Hsinchu (TW); Shou-Yi Hsu, Hsinchu (TW); Meng-Wei Wu, Hsinchu (TW); Main-Gwo Chen, Hsinchu (TW); Yi-Chun Shih, Hsinchu (TW)

(73) Assignee: ANPEC ELECTRONICS CORPORATION, Hsinchu (TW)

(21) Appl. No.: 13/238,189

(22) Filed: Sep. 21, 2011

(30) Foreign Application Priority Data
Jan. 13, 2011 (TW) 100101232

(51) Int. Cl. H01L 29/739

(52) U.S. Cl. 257/139; 257/E29.197

(57) ABSTRACT

An insulated gate bipolar transistor includes: a collector layer; a drift layer formed on and connected to the collector layer; a gate structure including a dielectric layer formed on the drift layer, and a conductive layer formed on the dielectric layer; a first emitter structure including a well region formed within the drift layer and partially connected to the dielectric layer of the gate structure, a source region formed within the well region just underneath a top surface of the well region, and a first electrode formed on the top surface of the well region and connected to the well region and the source region; and a second emitter structure spaced apart from the gate structure and the first emitter structure, and including a bypass region formed on the top surface of the drift layer, and a second electrode formed on the bypass region.

### CROSS-REFERENCE TO RELATED APPLICATION

This application claims priority of Taiwanese application No. 100101232, filed on Jan. 13, 2011.

### BACKGROUND OF THE INVENTION

1. Field of the Invention

This invention relates to an insulated gate bipolar transistor (IGBT), more particularly to an IGBT having a high switching speed.

2. Description of the Related Art

An insulated gate bipolar transistor (IGBT) is a power semiconductor device that combines a metal oxide silicon field effect transistor (MOSFET) having simple gate-drive and high-current characteristics, and a bipolar junction transistor (BJT) having low-saturation voltage capability. The IGBT is usually applied to a high power electric apparatus, such as a motor control apparatus.

Referring to FIG. 1, a conventional IGBT 1 includes a collector layer 11, adrift layer 12, a gate structure 13, and an emitter structure 14.

The collector layer 11 is a flat substrate that is composed of a p-type semiconductor material. The drift layer 12 is epitaxially formed on the collector layer 11, and is composed of an n-type semiconductor material.

The gate structure 13 includes a dielectric layer 131 that is formed on and connected to a top surface of the drift layer 12 opposite to the collector layer 11 and that is composed of an insulating material, and a conductive layer 132 that is formed on the dielectric layer 131 opposite to the drift layer 12 and that is used for electrically connecting to an external circuit.

The emitter structure 14 includes a well region 141 formed within the drift layer 12 just underneath the top surface of the drift layer 12, a source region 142 formed within the well region 141 just underneath a top surface of the well region 141, and an emitter electrode 143 formed on the top surface of the drift layer 12 and connected to the well region 141 and the source region 142. The well region 141 and the source region 142 are respectively composed of p-type and n-type semiconductor materials. The emitter electrode 143 is composed of a conductive material such as tungsten, and is used for connecting to an external circuit. It should be noted that the emitter electrode 143 is not electrically connected to the conductive layer 132 of the gate structure 13.

The collector layer 11, the drift layer 12, and the well region 141 cooperate to define a vertical BJT device. The drift layer 12, the gate structure 13, the well region 141, and the source region 142 cooperate to define a FET device. The vertical BJT device and the FET device are combined to form the IGBT 1.

When a predetermined forward voltage is applied between the conductive layer 132 of the gate structure 13 and the emitter electrode 143 of the emitter structure 14, i.e., the conductive layer 132 has a positive voltage, the FET device is switched on and forward biased, resulting in formation of an inversion channel in the well region 141 just underneath the dielectric layer 131. By virtue of the inversion channel, the FET device provides a base current for the BJT device, thereby turning on the IGBT 1. When the applied voltage is inverted or removed, the FET device is switched to a cutoff mode, thereby turning off the IGBT 1.

After the applied voltage is inverted or removed, slow combination of carriers and release of charge by parasitic capacitance formed at an interface of the well region 141 and the drift layer 12 are likely to occur, thereby resulting in a longer switching time for the IGBT 1 and thus arising in a problem of collector current tailing for the IGBT 1. (The interface is well to epi)

Moreover, when an excessively large current is formed, a parasitic thyristor composed of the collector layer 11, the drift layer 12, the emitter region 141, and the source region 142 may be turned on, resulting in failure in using the predetermined applied voltage to switch the IGBT 1, which causes loss of control for operating the IGBT 1.

### SUMMARY OF THE INVENTION

Therefore, the object of the present invention is to provide an insulated gate bipolar transistor that has a high switching speed and that can be stably controlled.

According to the present invention, an insulated gate bipolar transistor comprises: a collector layer having a first conductivity type; a drift layer formed on and connected to the collector layer and having a second conductivity type; a gate structure including a dielectric layer formed on a top surface of the drift layer opposite to the collector layer, and a conductive layer formed on the dielectric layer opposite to the drift layer; a first emitter structure including a well region that has the first conductivity type, that is formed within the drift layer, and that is partially connected to the dielectric layer of the gate structure, a source region that has the second conductivity type and that is formed within the well region just underneath a top surface of the well region, and a first electrode formed on the top surface of the well region and connected to the well region and the source region; and a second emitter structure spaced apart from the gate structure and the first emitter structure, and including a bypass region formed on the top surface of the drift layer, and a second electrode formed on the bypass region opposite to the drift layer.

### BRIEF DESCRIPTION OF THE DRAWINGS

Other features and advantages of the present invention will become apparent in the following detailed description of the preferred embodiment of the invention, with reference to the accompanying drawings, in which:

FIG. 1 is a schematic view showing a conventional insulated gate bipolar transistor; and

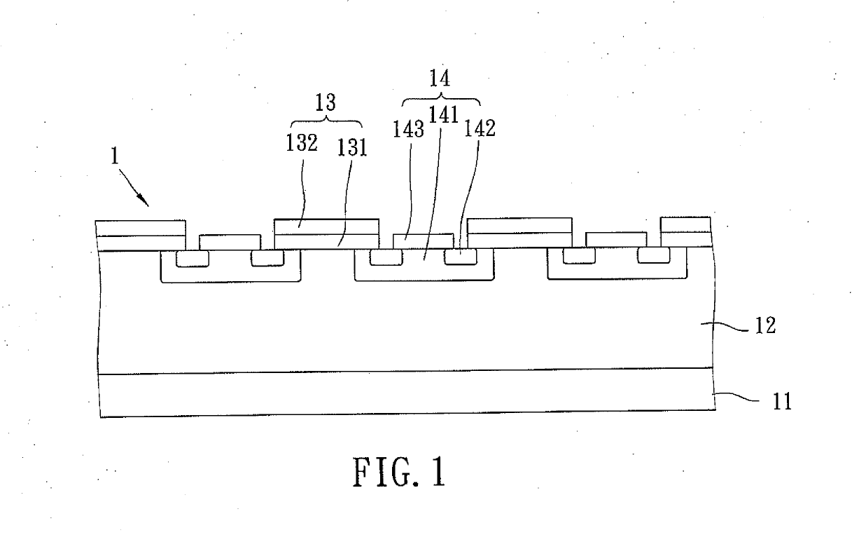

FIG. 2 is a schematic view showing the preferred embodiment of an insulated gate bipolar transistor according to the present invention.

### DETAILED DESCRIPTION OF THE PREFERRED EMBODIMENT

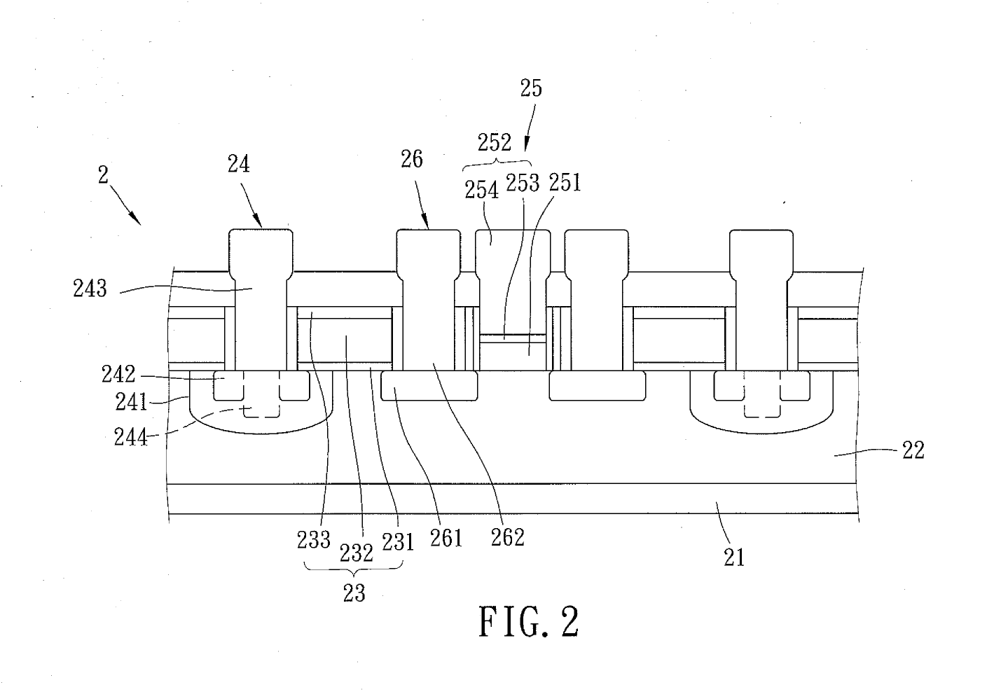

Referring to FIG. 2, the preferred embodiment of an insulated gate bipolar transistor (IGBT) 2 according to the present invention comprises a collector layer 21, a drift layer 22, a gate structure 23, a first emitter structure 24, and a second emitter structure 25.

The collector layer 21 is composed of a first type semiconductor material, and thus has a first conductivity type. In this embodiment, the collector layer 21 is in the form of a flat substrate.

The drift layer 22 is epitaxially formed on and connected to the collector layer 21, and is composed of a second type semiconductor material and thus has a second conductivity type.

The gate structure 23 includes a dielectric layer 231 formed on a top surface of the drift layer 22 opposite to the collector layer 21, and a conductive layer 232 formed on the dielectric layer 231 opposite to the drift layer 22, i.e., the conductive layer 232 is electrically insulated from the drift layer 22 by the dielectric layer 231. Preferably, the gate structure 23 further includes a hard protective layer 233 formed on the conductive layer 232 for preventing damage to the conductive layer 232 during an etching or cleaning process.

The first emitter structure 24 includes a well region 241 that has the first conductivity type, that is formed within the drift layer 22 just underneath the top surface of the drift layer 22, and that is partially connected to the dielectric layer 231 of the gate structure 23; a source region 242 that has the second conductivity type, that is formed within the well region 241 just underneath a top surface of the well region 241, and that is partially connected to the dielectric layer 231 of the gate structure 23; and a first electrode 243 that is formed on the top surface of the well region 241 and connected to the well region 241 and the source region 242, that is electrically isolated from the conductive layer 232 of the gate structure 23, and that is used for connecting to an external circuit. The source region 242 has a majority carrier concentration not smaller than that of the drift layer 22.

The well region 241 includes a high concentration area 244 that is formed just underneath and connected to the first electrode 243, and that is surrounded by the source region 242. The high concentration area 244 of the well region 241 is not connected to the dielectric layer 231 of the gate structure 23. The high concentration area 244 has a majority carrier concentration larger than that of the remainder of the well region 241 and not larger than that of the collector layer 21, i.e., the total majority carrier concentration of the well region 241 is not larger than that of the collector layer 21.

The second emitter structure 25 is spaced apart from the gate structure 23 and the first emitter structure 24, and includes a bypass region 251 formed on the top surface of the drift layer 22, a second electrode 252 that is formed on the bypass region 251 opposite to the drift layer 22 and that is used for connecting to an external circuit, and an adhesive layer 253 disposed between the bypass region 251 and the second electrode 254. The bypass region 251 is insulated from the collector layer 21 by the drift layer 22, and has a first conductivity type and a majority carrier concentration not larger than that of the collector layer 21. The adhesive layer 253 is mostly composed of a metal silicide selected from the group consisting of titanium silicide, tungsten silicide, tantalum silicide, and combinations thereof. The second electrode 254 is mostly composed of a metal selected from the group consisting of tungsten, aluminum, copper, and combinations thereof.

Preferably, the IGBT 2 further includes a base structure 26 having a base region 261 that is formed within the drift layer 22 just underneath the top surface of the drift layer 22, and a third electrode 262 that is formed on a top surface of the base region 261 and connected to the base region 261, and that is spaced apart from the gate structure 23 and the first and second emitter structures 24, 25. The base region 261 has the second conductivity type and a majority carrier concentration not smaller than that of the drift layer 22, and is electrically isolated from the bypass region 251 of the second emitter structure 25 through the drift layer 22. The third electrode 262 is mostly composed of a metal such as tungsten, aluminum, and copper, and is used for connecting to an external circuit.

It should be noted that each of the first electrode 243 of the first emitter structure 24, the second electrode 252 of the second emitter structure 25, and the third electrode 262 of the base structure 26 is electrically isolated from the conductive layer 232 of the gate structure 23 using, e.g., an insulating layer composed of an insulating material. In addition, adhesive layers (not shown) may be formed between the high concentration area 244 of the well region 241 and the first electrode 243, and between the base region 261 and the third electrode 262, for improving the connection and attracting charges when the IGBT 2 is turned off.

The collector layer 21, the drift layer 22, and the well region 241 cooperate to define a first vertical BJT device. The collector layer 21, the drift layer 22, and the bypass region 251 cooperate to define a second vertical BJT device. The drift layer 22, the gate structure 23, the well region 241, and the source region 242 cooperate to define a FET device, which combines with the first and second vertical BJT devices to form the IGBT 2 of the present invention.

The first and second conductivity types mentioned above may be respectively p-type and n-type, or may be respectively n-type and p-type, according to practical requirements. In this embodiment, the first and second conductivity types are respectively exemplified to be p-type and n-type for illustration.

When a predetermined forward voltage is applied between the conductive layer 232 and the first electrode 243, i.e., the conductive layer 232 has a positive voltage, the FET device is switched on and forward biased, resulting in formation of an inversion channel in the well region 241 that disposed just underneath the dielectric layer 231. The inversion channel provides a base current for both of the first and second BJT devices, thereby generating an emitter current and turning on the IGBT 2. When the applied forward voltage is inverted or removed, the FET device is switched off and no inversion channel is formed, thereby turning off the IGBT 2.

Specifically, since, in the IGBT 2 of this invention, two BJT devices are provided, the emitter current of the IGBT 2 is split, and thus, the individual emitter current in each of the first and second emitter structures 24, 25 is reduced, thereby preventing formation of a parasitic thyristor composed of the collector layer 21, the drift layer 22, the well region 241, and the source region 242. Accordingly, the IGBT 2 can be operated stably.

In addition, the equivalent base width of the second BJT device may be adjusted by varying the majority carrier concentration of the base region 261 of the base structure 26, which may reduce the equivalent conduction resistance of the IGBT 2 when the IGBT 2 is turned on. When the majority carrier concentration of the base region 261 is increased, the base current of the second BJT device increases due to the reduced conduction resistance, thereby increasing the emitter current of the IGBT 2.

When the applied voltage between the conductive layer 232 and the first electrode 243 is inverted or removed, the carriers in the drift layer 22 may recombine not only in the well region 241 of the first emitter structure 24 but also in electric fields formed in the base region 261 and the bypass region 251, thereby reducing the switching time of the IGBT 2. Moreover, with the bypass region 251, turn-on of the parasitic thyristor could be alleviated, thereby reducing the possibility of failure in operation of the IGBT 2. In addition, the adhesive layer 253 of the second electrode 252 may attract charges so as to alleviate the problem of collector current tailing.

While the present invention has been described in connection with what is considered the most practical and preferred embodiment, it is understood that this invention is not limited to the disclosed embodiment but is intended to cover various arrangements included within the spirit and scope of the broadest interpretations and equivalent arrangements.

What is claimed is:

1. An insulated gate bipolar transistor, comprising:
a collector layer having a first conductivity type;
adrift layer formed on and connected to said collector layer and having a second conductivity type;
a gate structure including a dielectric layer formed on a top surface of said drift layer opposite to said collector layer, and a conductive layer formed on said dielectric layer opposite to said drift layer;
a first emitter structure including a well region that has said first conductivity type, that is formed within said drift layer, and that is partially connected to said dielectric layer of said gate structure, a source region that has said second conductivity type and that is formed within said well region just underneath a top surface of said well region, and a first electrode formed on said top surface of said well region and connected to said well region and said source region; and
a second emitter structure spaced apart from said gate structure and said first emitter structure, and including a bypass region formed on said top surface of said drift layer, and a second electrode formed on said bypass region opposite to said drift layer.

2. The insulated gate bipolar transistor of claim 1, further comprising a base structure including a base region that is formed within said drift layer, and that has said second conductivity type and a majority carrier concentration not smaller than that of said drift layer.

3. The insulated gate bipolar transistor of claim 2, wherein said base structure further includes a third electrode formed on a top surface of said base region and connected to said base region, said third electrode being spaced apart from said gate structure and said first and second emitter structures.

4. The insulated gate bipolar transistor of claim 1, wherein said second emitter structure further includes an adhesive layer disposed between said bypass region and said second electrode.

5. The insulated gate bipolar transistor of claim 1, wherein said bypass region has a majority carrier concentration not larger than that of said collector layer.

6. The insulated gate bipolar transistor of claim 1, wherein said well region of said first emitter structure has a majority carrier concentration not larger than that of said collector layer.

7. The insulated gate bipolar transistor of claim 1, wherein said well region of said first emitter structure includes a high concentration area that is formed just beneath and connected to said first electrode, that is surrounded by the source region, and that has said first conductivity type, said high concentration area having a majority carrier concentration larger than that of the remainder of said well region.

8. The insulated gate bipolar transistor of claim 1, wherein said source region of said first emitter structure has a majority carrier concentration not smaller than that of said drift layer.

9. The insulated gate bipolar transistor of claim 1, wherein said first conductivity type is p-type and said second conductivity type is n-type.

10. The insulated gate bipolar transistor of claim 1, wherein said first conductivity type is n-type and said second conductivity type is p-type.
